(19) United States
(12) Patent Application Publication
(10) Pub. No.: US 2007/0159800 A1
(43) Pub. Date: Jul. 12, 2007

(54) Cabinet for electric apparatus

(75) Inventor: Shinji Matsui, Osaka (JP)

Correspondence Address: OSHA LIANG L.L.P., 1221 MCKINNEY STREET, SUITE 2800, HOUSTON, TX, 77010, US

(73) Assignee: Funai Electric Co., Ltd., Daito-shi (JP)

(21) Appl. No.: 11/651,704

(22) Filed: Jan. 10, 2007

(30) Foreign Application Priority Data
Jan. 10, 2006 (JP) 2006-002500

(51) Int. Cl. H05K 5/00

(52) U.S. Cl. 361/724

(57) ABSTRACT

A top case coupled to a bottom case to form a cabinet main body, a front face of which is opened. A front panel attached to the opened front face of the cabinet main body. Each of the bottom case, the top case and the front panel is made of resin molding material. The bottom case and the front panel are coupled via a first insertion structure which is formed by a first projection portion protruding from the bottom case and a first concave portion which is provided at the front panel and into which the first projection portion is press-fitted. The top case and the front panel are coupled via a second insertion structure which is formed by a second projection portion protruding from the top case and a second concave portion which is provided at the front panel and into which the second projection portion is press-fitted. The bottom case and the top case are coupled via a fitting structure which is formed by a concave groove portion, which extends in front and rear direction along an entire length of a side wall of the bottom case, and a projection portion which is provided along an entire length of a side wall of the top case and is sidably fitted into the concave groove portion. A screw cramping structure as a first positioning means prevents a displacement between the cabinet main body and the bottom case in front and rear direction. Another screw cramping structure as a second positioning means prevents a displacement between the bottom case and the top case.

The disclosure of Japanese Patent Application No. 2006-002500 filed Jan. 10, 2006 including specification, drawings and claims is incorporated herein by reference in its entirety.

### BACKGROUND

The present invention relates to a cabinet for an electric apparatus and, in particular, relates to a cabinet adapted to accommodate the electric apparatus and includes a bottom case, a top case and a front case.

In many cases, a cabinet for an electric apparatus is configured by a bottom case, a top case, and a front case (see Japanese Patent Publication No. 2000-163939A, Japanese Patent Publication No. 2002-251876A, Japanese Patent Publication No. 10-145048A, and Japanese Utility Model Publication No. 5-85074A, for example).

The Japanese Patent Publication No. 2000-163939A discloses a case structure for a magnetic recording apparatus. In the Japanese Patent Publication No. 2000-163939A, hook pieces provided at the both ends of a front panel are engaged with engaging holes formed at the side chassis of the case respectively, in a case where the front panel is attached to the front face of the case.

The Japanese Patent Publication No. 2002-251876A discloses a cabinet structure in which the attachment portion of an embedded tape deck is prevented from being drawn out from a boss on a chassis side. Further, in the Japanese Patent Publication No. 10-145048A and the Japanese Utility Model Publication No. 5-85074A, it is proposed to omit a screw cramp from a front panel attachment structure.

However, as disclosed in the Japanese Patent Publication No. 2000-163939A, the engagement portions between the hook pieces and the engaging holes are exposed on the side surfaces of the case. Thus, the engagement portions are visible when viewed from outside of the case during the usual using state of the electric apparatus, whereby the external appearance of the cabinet may be degraded. Even in the case where the engagement portions between the hook pieces and the engaging holes are formed on the bottom surface of the cabinet, since the engagement portions are noticeable while handling the cabinet, the external appearance of the cabinet may also be degraded. In addition, the electric apparatus may be used in a state that the cabinet stands in a longitudinal direction thereof. Therefore, the bottom surface of the cabinet is varied in accordance with the using state of the electric apparatus. In order to solve such a problem, it is considered to attach a blind cover to the engagement portion between the hook piece and the engaging hole so that the engagement portion is not visible when viewed from the outside. However, in this case, since the cover is additionally required, the number of parts and the number of assembling procedure are increased, which likely results in the cost-up as a whole.

### SUMMARY

It is therefore an object of the invention to provide cabinet for an electric apparatus in which the bottom case, the top case, and the front panel are coupled with each other by a coupling structure which is not visible when viewed from any point external to the cabinet, thereby providing good external appearance, in place of the engagement portions between the hook pieces and the engaging holes that are visible when viewed from the outside like the Japanese Patent Publication No. 2000-163939A

Further, it is also an object of the invention to provide a cabinet for an electric apparatus in which the assembling performance of the cabinet is enhanced and the cabinet can be assembled easily, accurately, with a high productivity and at a low cost.

In order to achieve the above-described objects, a cabinet adapted to accommodate an electric apparatus, comprising:

a first case;

a second case attached to the first case;

a third case;

a first projection provided on one of the first case and the third case;

a first engagement part provided on the other one of the first case and the third case and engaging with the first projection so that the first case and the third case are coupled with each other;

a second projection provided on one of the second case and the third case; and

a second engagement part provided on the other one of the second case and the third case and engaging with the second projection so that the second case and the third case are coupled with each other, wherein:

the first projection, the first engagement part, the second projection and the second engagement part are not visible when the first case, the second case and the third case are coupled with each other.

With this configuration, the external appearance of the cabinet becomes good.

The first projection may be provided on one of an inner face of the first case and an inner face of the third case; and

The second projection may be provided on one of an inner face of the second case and the inner face of the third case.

The first engagement part may be provided on one of an inner face of the first case and an inner face of the third case; and

The second engagement part may be provided on one of an inner face of the second case and the inner face of the third case.

The first projection may be provided on one of a contact face of the first case, which is in contact with the third case and a contact face of the third case, which is in contact with the first case.

The second projection may be provided on one of a contact face of the second case, which is in contact with the third case and the contact face of the third case, which is in contact with the second case.

The first engagement part may be provided on one of a contact face of the first case, which is in contact with the third case and a contact face of the third case, which is in contact with the first case.

The second engagement part may be provided on one of a contact face of the second case, which is in contact with the third case and the contact face of the third case, which is in contact with the second case.

The first case, the second case, and the third case may be comprised of resin.

The cabinet may further comprise:

a third projection provided on one of the first case and the second case;

a third engagement part provided on the other one of the first case and the second case and engaging with the third projection so that the first case and the third case are sidably coupled with each other.

With this configuration, in the assembling line of the cabinet, by merely sliding the first case with respect to the second case so as to engage the third projection with the third engagement part, the first projection is engaged with the first engagement part, and the second projection is also engaged with the second engagement part since the first case and the second case are positionally adjusted with respect to the third case. Therefore, the assembling performance of the cabinet is improved, the productivity thereof is also increased, and the assembling accuracy is also improved.

The third projection may be provided on one of a contact face of the first case, which is in contact with the second case and a contact face of the second case, which is in contact with the first case.

The third engagement part may be provided on one of a contact face of the first case, which is in contact with the second case and a contact face of the second case, which is in contact with the first case.

With this configuration, since the third projection and the third engagement part is not visible when viewed from any point external to the cabinet when the cases are coupled with each other, the external appearance of the cabinet becomes good.

The cabinet may further comprise:

a first fixing structure fixing the first case and the second case to the third case so as to prevent a displacement;

a second fixing structure which fixes the first case to the second case.

With this configuration, the assembled cabinet becomes firm.

The first fixing structure may include a screw.

The second fixing structure may include a screw.

With this configuration, the first case and the third case are sufficiently secured.

The first fixing structure may be provided on one of an outer face of the first case and an outer face of the second case.

The second fixing structure may be provided on one of an outer face of the first case and an outer face of the second case.

According to the invention there is also provided a cabinet for an electric apparatus comprising:

a bottom case;

a top case coupled to the bottom case to form a cabinet main body, a front face of which is opened; and

a front panel attached to the opened front face of the cabinet main body, wherein:

each of the bottom case, the top case and the front panel is made of resin molding material;

the bottom case and the front panel are coupled via a first insertion structure which is formed by a first projection portion protruding from the bottom case and a first concave portion which is provided at the front panel and into which the first projection portion is press-fitted;

the top case and the front panel are coupled via a second insertion structure which is formed by a second projection portion protruding from the top case and a second concave portion which is provided at the front panel and into which the second projection portion is press-fitted;

the bottom case and the top case are coupled via a fitting structure which is formed by a concave groove portion, which extends in front and rear direction along an entire length of a side wall of the bottom case, and a projection portion which is provided along an entire length of a side wall of the top case and is sidably fitted into the concave groove portion; and

the cabinet further comprises a screw cramping structure as a first positioning means, which prevents a displacement between the cabinet main body and the bottom case in front and rear direction, and another screw cramping structure as a second positioning means, which prevents a displacement between the bottom case and the top case.

With this configuration, in a case where the cabinets are not recommended to be disassembled by a user, since the first insertion structure, the second insertion structure, and the fitting structure is not visible when viewed from any point external to the cabinet, the user can not easily find the method of disassembling the cabinet. Further, in the assembling line of the cabinets, advantageously, the productivity of the assembling of the cabinets can be improved and the assembling can be made with a high accuracy.

### BRIEF DESCRIPTION OF THE DRAWINGS

The above objects and advantages of the present invention will become more apparent by describing in detail preferred exemplary embodiments thereof with reference to the accompanying drawings, wherein:

FIG. 1 is a schematic perspective outside view of a cabinet for an electric apparatus according to an embodiment of the invention;

FIG. 2 is a schematic perspective view showing the procedure of coupling a bottom case with a front panel;

FIG. 3 is a schematic perspective view showing the procedure of coupling the front panel with a top case;

FIG. 4 is a partly sectional plan view showing a coupling portion between the bottom case and the front panel;

FIG. 5 is a partly sectional plan view showing a coupling portion between the front panel and the top case;

FIG. 6 is a section view showing an example of a screw cramping structure serving as a first positioning means;

FIG. 7 is a partly sectional side view of the cabinet for the electric apparatus; and

FIG. 8 is a section view showing an example of a screw cramping structure serving as a second positioning means.

### DETAILED DESCRIPTION OF THE EMBODIMENTS

Hereinafter, an embodiment of a cabinet for an electric apparatus according to the invention will be discussed with reference to the accompanying drawings.

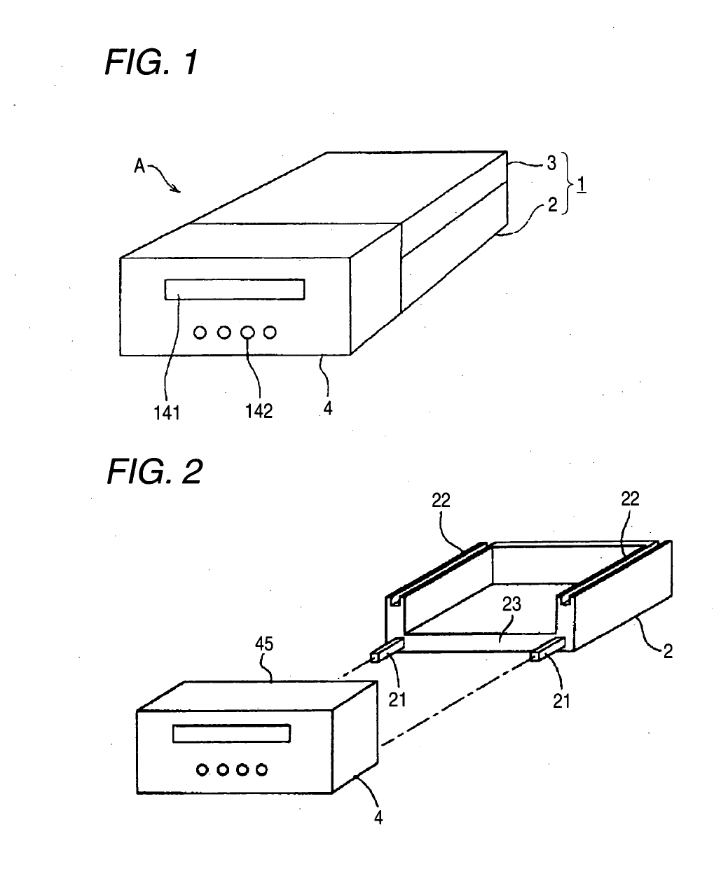

As shown in FIG. 1, a cabinet A for an electric apparatus is formed by assembling a bottom case (chassis) 2, a top case 3 and a front panel 4 in a flat box shape. The bottom case 2, a top case 3, and a front panel 4 are made of resin mold material. The top case 3 is piled on the bottom case 2 and coupled therewith, thereby forming a cabinet main body 1 which front face is opened. The front panel 4 is attached to the opened front face of the cabinet main body 1. A DVD drive, a CD drive or a VTR unit, for example, is embedded in the electric apparatus cabinet A, and hence the cabinet is used as an audio visual apparatus etc. The front panel 4 is provided with operation mode selection buttons 142 and an elongated opening 141 into and from which a disc or a tape cassette etc. serving as a recording medium is inserted and extracted.

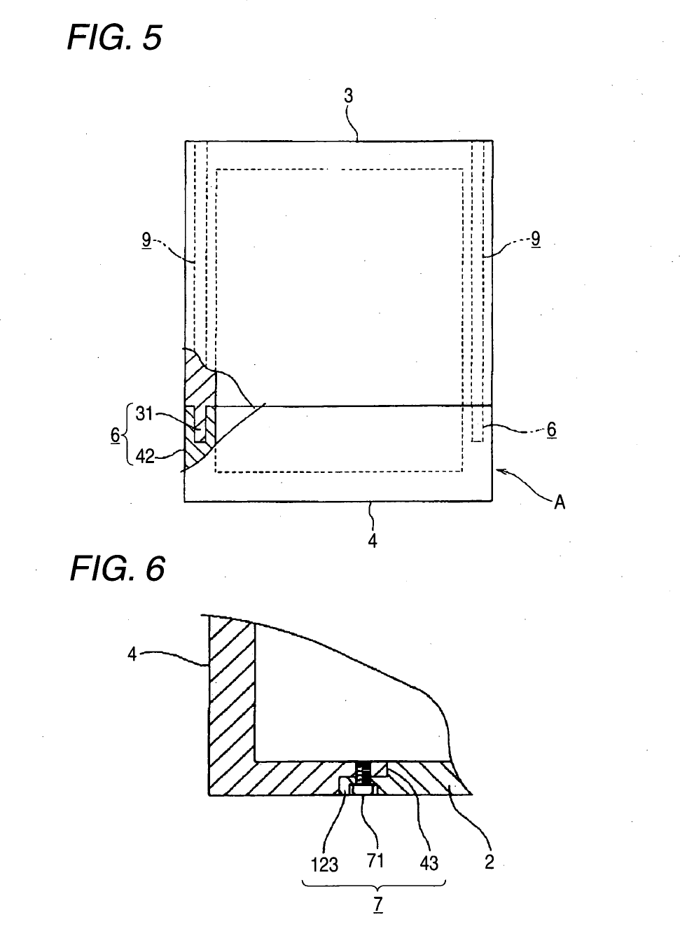

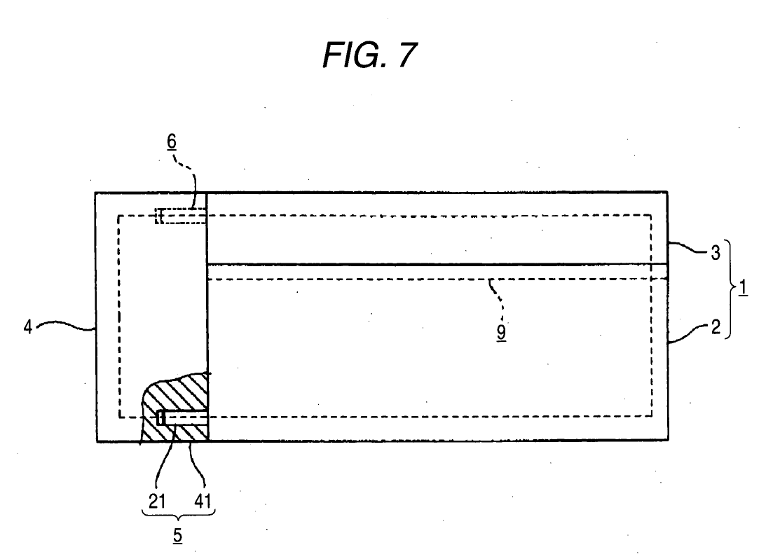

In the electric apparatus cabinet A, as shown in FIGS. 4 and 7, the bottom case 2 and the front panel 4 are coupled with each other by first insertion structures 5. Each of the first insertion structures 5 is formed by inserting an elongated first projection portion 21, which protrudes straightly in a forward direction from a front end face of the bottom case 2, into a concave-shaped first hole portion 41 provided at the case 4. In an example shown in FIG. 4, the first insertion structure 5 is provided at the left and right sides of the contact faces of the bottom case 2 and the front panel 4 in a symmetrical manner. Further, as shown in FIG. 5, the top case 3 and the front panel 4 are coupled with each other by second insertion structures 6. Each of the second insertion structures 6 is formed by inserting an elongated second projection portion 31 which protrudes straightly in a forward direction from a front end face of the top case 3, into a concave-shaped second hole portion 42 provided at the case 4. In an example shown in FIG. 5, the second insertion structure 6 is provided at the left and right sides of the contact faces of the top case 3 and the front panel 4 in a symmetrical manner.

In this respect, it is not preferable that the first insertion structure 5 jolts at the insertion portion between the first projection portion 21 and the first hole portion 41 or that the second insertion structure 6 jolts at the insertion portion between the second projection portion 31 and the second hole portion 42. Thus, in this embodiment, the sizes of the first projection portion 21 and the first hole portion 41 of each of the first insertion structures 5 and also the sizes of the second projection portion 31 and the second hole portion 42 of each of the second insertion structures 6 are set so that the respective insertion portions do not jolt. In particular, when the first projection portion 21 and the second projection portion 31 are press-fitted into the first hole portion 41 and the second hole portion 42, respectively, the bottom case 2 and the top case 3 are firmly coupled with the front panel 4, whereby a sufficiently large coupling intensity can be obtained.

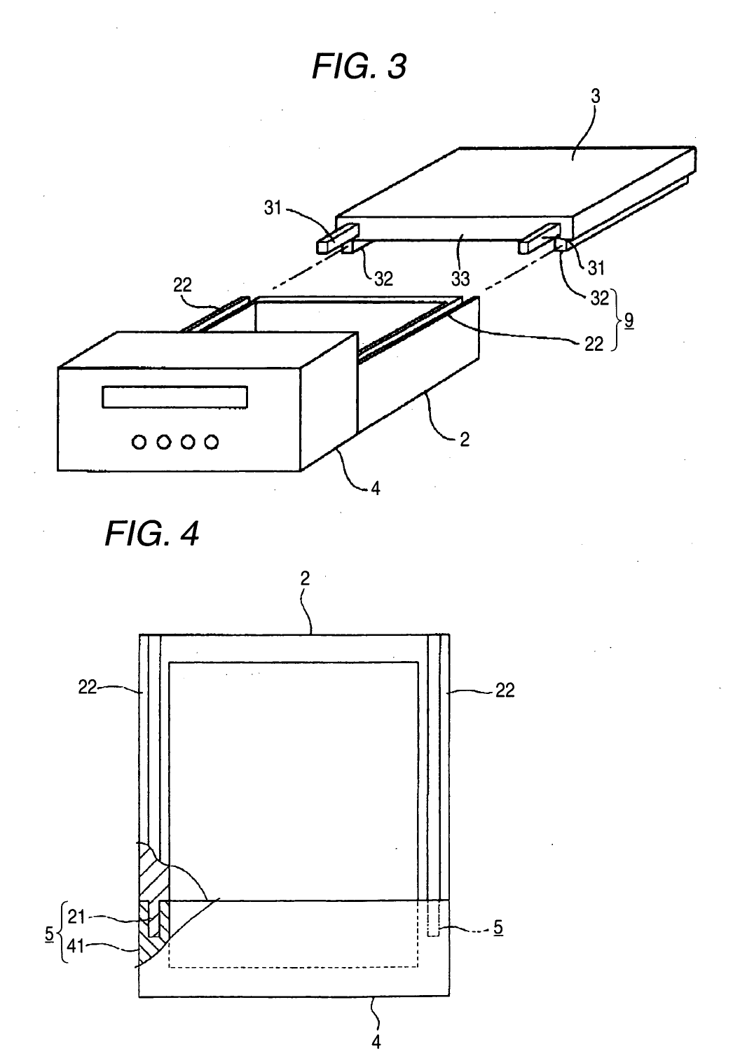

As shown in FIGS. 3 and 5, in this electric apparatus cabinet A, the bottom case 2 and the top case 3 are coupled via fitting structures 9 each formed by a straight concave groove portion 22, which is formed on an upper end of a side wall of the bottom case 2 and extends in the longitudinal direction along the entire length of the side wall thereof, and a straight projection portion 32, which is formed on a lower end of a side wall of the top case 3 and extends in the longitudinal direction along the entire length of the side wall thereof. When the projection portion 32 is press-fitted into the concave groove portion 22, each of the fitting structures 9 does not jolt between the concave groove portion 22 and the projection portion 32, whereby the coupling intensity of the bottom case 2 and the top case 3 is enhanced and so the cabinet main body 1 can be configured firmly.

According to the electric apparatus cabinet A configured as explained above, the bottom case 2 and the top case 3 forming the cabinet main body 1 are coupled with each other via the fitting structures 9, and the cabinet main body 1 and the front panel 4 are coupled with each other via the first insertion structures 5 and the second insertion structures 6. In addition, this embodiment employs a screw cramping structure 7 as a first positioning means for preventing a displacement between the cabinet main body 1 and the front panel 4 in the front and rear directions thereby to enhance the coupling intensity therebetween. This embodiment further employs a screw cramping structure 8 as a second positioning means for preventing the displacement between the bottom case 2 and the top case 3 thereby to further enhance the coupling intensity therebetween. With these screw cramping structures 7 and 8, it is possible to completely eliminate a fear that the fitting structures 9 or the first and second insertion structures 5, 6 may disengage due to a shock caused by the falling of the cabinet etc.

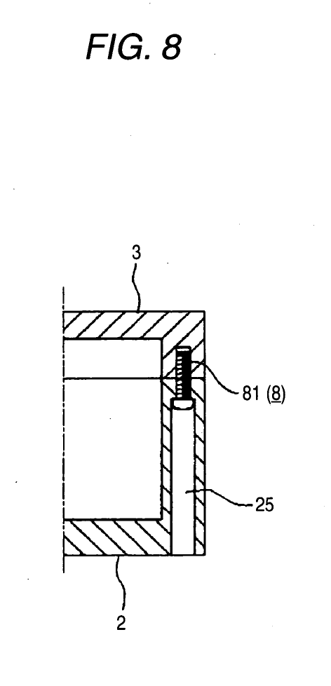

As shown in FIG. 6, the screw cramping structure 7 as the first positioning means is arranged in a manner that an overlapped portion between a receiving portion 123 at a front end of the bottom case 2 and a projection piece portion 43 integrally provided at a lower end of the front panel 4 is screwed by a cramping screw 71 screwed from the rear surface side of the bottom case 2. The screw cramping structure 7 is employed at each of the left and right side of overlapped portions. According to this configuration, the separation between the cabinet main body 1 and the front panel 4 due to a shock caused by the falling of the cabinet etc. can be prevented. Further, as shown in FIG. 8, the screw cramping structure 8 as the second positioning means is arranged in a manner that an overlapped portion between the bottom case 2 and the top case 3 is screwed by a cramping screw 81 screwed from the rear surface side of the bottom case 2. The screw cramping structure 8 is desirably employed at each of the left and right overlapped portions. According to this configuration, the separation between the bottom case 2 and the top case 3 due to a shock caused by the falling of the cabinet etc. can be prevented. As shown in FIG. 8, a head portion of the cramping screw 81 is housed within a screw pocket 25 provided at a bottom face of the bottom case 2 thereby to prevent the cramping screw 81 from exposing on the outer surface side. Since the screw cramping structures 7 and 8 as described above are employed, the firm electric apparatus cabinet A can be configured.

Next, the assembling procedure of the electric apparatus cabinet A will be explained with reference to FIGS. 2 and 3.

In the first step, as shown in FIG. 2, the first projection portions 21 of the bottom case 2 are inserted into the first hole portions 41 (see FIGS. 4 and 7) of the front panel, respectively, thereby putting the rear end face (contact face) 45 of the front panel 4 together with a front end face (contact face) 23 of the bottom case 2. In the next step, as shown in FIG. 3, the projection portions 32 of the top case 3 are fit into the concave groove portions 22 of the bottom case 2 and slide the top case 3 with respect to the bottom case 2, whereby the second projection portions 31 of the top case 3 are inserted into the second hole portions 42 (see FIG. 5) of the front panel 4, respectively, thereby putting the rear end face (contact face) 45 of the front panel 4 and the front end face (contact face) 33 of the top case 3 together. Then, if necessary, the screw cramping structures 7 and 8 explained with reference to FIG. 6 or FIG. 8 are added. When such the assembling procedure is employed, the electric apparatus cabinet A can be assembled easily with a high accuracy. Further, since the related-art engagement structure of the engaging hole and the hook piece is not employed, it becomes possible to avoid such phenomena that the engagement portion therebetween are visible to degrade the external appearance of the cabinet and that the number of parts and the number of assembling procedure increase due to the attachment of the blind cover to the engagement portion.

In the electric apparatus cabinet of the invention, the first projection portions 21 and the second projection portions 31 may be provided at the front cabinet, and the first hole portions 41 and the second hole portions 42 of the front cabinet may be provided at the bottom case 2 or the top case 3. Further, the concave groove portions 22 may be provided at the top case 3, and the projection portions 22 of the top case 3 may be provided at the bottom case 2.

In the electric apparatus cabinet of the invention, the first projection portions 21, the second projection portions 31, and the projection portions 32 may be integrally provided at one of the top case 3, bottom case 2, or the front panel 4 respectively.

In the electric apparatus cabinet of the invention, the top case 3 may be used as a bottom case and the bottom case 2 may be used as a top case.

In the electric apparatus cabinet of the invention, the first hole portion and the second hole portion are not limited to be hole-shaped. The concave groove portion is not limited to be groove-shaped. Any shapes which can engaging or coupling with the corresponding projection portions can be employed as the first hole portion, the second hole portion, and the concave groove portion.

In the electric apparatus cabinet of the invention, the first insertion structures, the second insertion structures, and the fitting structures are not limited to be provided on the contact faces of the bottom case, the top case, or the front panel. The structures may be provided at any positions where the structures are not visible when viewed from any point external to the cabinet. Namely, the first insertion structures, the second insertion structures, and the fitting structures may be provided on an inner face of the bottom case, the top case, or the front panel.

What is claimed is:

1. A cabinet for an electric apparatus comprising:
a bottom case;
a top case coupled to the bottom case to form a cabinet main body, a front face of which is opened; and
a front panel attached to the opened front face of the cabinet main body, wherein:
each of the bottom case, the top case and the front panel is made of resin molding material;
the bottom case and the front panel are coupled via a first insertion structure which is formed by a first projection portion protruding from the bottom case and a first concave portion which is provided at the front panel and into which the first projection portion is press-fitted;
the top case and the front panel are coupled via a second insertion structure which is formed by a second projection portion protruding from the top case and a second concave portion which is provided at the front panel and into which the second projection portion is press-fitted;
the bottom case and the top case are coupled via a fitting structure which is formed by a concave groove portion, which extends in front and rear direction along an entire length of a side wall of the bottom case, and a projection portion which is provided along an entire length of a side wall of the top case and is sidably fitted into the concave groove portion; and
the cabinet further comprises a screw cramping structure as a first positioning means, which prevents a displacement between the cabinet main body and the bottom case in front and rear direction, and another screw cramping structure as a second positioning means, which prevents a displacement between the bottom case and the top case.

2. A cabinet adapted to accommodate an electric apparatus, comprising:
a first case;
a second case attached to the first case;
a third case;
a first projection provided on one of the first case and the third case;
a first engagement part provided on the other one of the first case and the third case and engaging with the first projection so that the first case and the third case are coupled with each other;
a second projection provided on one of the second case and the third case; and
a second engagement part provided on the other one of the second case and the third case and engaging with the second projection so that the second case and the third case are coupled with each other, wherein:
the first projection, the first engagement part, the second projection and the second engagement part are not visible when the first case, the second case and the third case are coupled with each other.

3. The cabinet as set forth in claim 2, wherein:
the first projection is provided on one of an inner face of the first case and an inner face of the third case; and
the second projection is provided on one of an inner face of the second case and the inner face of the third case.

4. The cabinet as set forth in claim 2, wherein:
the first engagement part is provided on one of an inner face of the first case and an inner face of the third case; and
the second engagement part is provided on one of an inner face of the second case and the inner face of the third case.

5. The cabinet as set forth in claim 2, wherein:
the first projection is provided on one of a contact face of the first case, which is in contact with the third case and a contact face of the third case, which is in contact with the first case; and
the second projection is provided on one of a contact face of the second case, which is in contact with the third case and the contact face of the third case, which is in contact with the second case.

6. The cabinet as set forth in claim 2, wherein:
the first engagement part is provided on one of a contact face of the first case, which is in contact with the third case and a contact face of the third case, which is in contact with the first case; and
the second engagement part is provided on one of a contact face of the second case, which is in contact with the third case and the contact face of the third case, which is in contact with the second case.

7. The cabinet as set forth in claim 2, wherein:
the first case, the second case, and the third case are comprised of resin.

8. The cabinet as set forth in claim 2, further comprising:
a third projection provided on one of the first case and the second case;
a third engagement part provided on the other one of the first case and the second case and engaging with the third projection so that the first case and the third case are slidably coupled with each other.

9. The cabinet as set forth in claim 8, wherein:
the third projection is provided on one of a contact face of the first case, which is in contact with the second case and a contact face of the second case, which is in contact with the first case.

10. The cabinet as set forth in claim 8, wherein:
the third engagement part is provided on one of a contact face of the first case, which is in contact with the second case and a contact face of the second case, which is in contact with the first case.

11. The cabinet as set forth in claim 2, further comprising:
a first fixing structure fixing the first case and the second case to the third case so as to prevent a displacement;
a second fixing structure which fixes the first case to the second case.

12. The cabinet as set forth in claim 11, wherein:
the first fixing structure includes a screw.

13. The cabinet as set forth in claim 11, wherein:
the second fixing structure includes a screw.
